(19) United States
(12) Patent Application Publication
(10) Pub. No.: US 2014/0311727 A1
(43) Pub. Date: Oct. 23, 2014

(54) Air Conditioner Terminal Device, Air Conditioning Apparatus And Data Center

(71) Applicant: Carrier Corporation, Farmington, CT (US)

(72) Inventors: YuHui Kuang, Shanghai (CN); Robert Hong-Leung Chiang, Shanghai (CN); Michel Grabon, Bressolles (FR); Lijia Jessica Zhao, Shanghai (CN)

(73) Assignee: Carrier Corporation, Farmington, CT (US)

(21) Appl. No.: 14/358,097

(22) PCT Filed: Nov. 15, 2012
(86) PCT No.: PCT/US2012/065151

§ 371 Date: May 14, 2014

(30) Foreign Application Priority Data
Nov. 15, 2011 (CN) 201120451181.1

(51) Int. Cl. H05K 7/20

(52) U.S. Cl. CPC H05K 7/2029
USPC 165/287; 165/121

(57) ABSTRACT

The invention discloses an air conditioner terminal device (100), an air conditioning apparatus and a data center (1000), wherein the air conditioner terminal device (100) comprises an air passage (101) communicating from an air suction port (11) to an air discharge port (21), a heat exchanger (12) and a variable-speed fan (22) which forces air in the air passage (101) to flow towards the air discharge port (21) from the air suction port (11) are installed in the air passage (101), and both the air suction port (11) and the air discharge port (21) are open downwardly. Therefore, air circulation can be improved and refrigerating capacity of the air conditioner terminal device can be increased.

### FIELD OF THE INVENTION

The invention relates to the technical field of air conditioner, and in particular to an air conditioner terminal device, an air conditioning apparatus having the air conditioner terminal device and a data center having the air conditioning apparatus.

### BACKGROUND

A data center comprises numerous data devices having high heat density electronic loads, such as computer, server, etc. Sensible heat generated by such loads is higher than that of a general cozy environment. Moreover, a non-stopped refrigerating for 365 days a year, 24 hours a day is required. Heat generation and sensitivities of electronic components require that the temperature, humidity, air flow and air cleanliness in the machine room must be maintained within a strict range, and that a highly stable operating environment is maintained. With continuous development of modern technologies, the scale of data center is being increasingly enlarged, and heat density of load is becoming higher and higher, thus causing more problems to heat processing of the machine room. Besides, higher requirements have been raised on reliability, high efficiency and energy-saving operation of air conditioning system.

A conventional hydronic fan coil unit (FCU) uses water as fluid medium in conduit. Some direct expansion FCU uses mixture of refrigerant and oil as fluid medium. Therefore, both of these FCUs present a reliability risk to the data device in the event of a coil leak which can lead to water or oil residues inside the data device.

On the other hand, for the conventional hydronic FCU, both the coil and the fan are assembled into a whole in the factory. When maintenance, it is required to detach all of the FCU and it will take a lot of time to deal with connections of piping and wiring, which will be adverse for quickly repairing the data center so that the data devices will operate for a long time in an environment without air conditioner to provide normal refrigerating, thus also bringing about risks to the data devices.

It is therefore necessary to provide improved technical solutions to overcome technical problems existing in the prior art.

### SUMMARY

The main technical problem to be solved by the invention is to provide reliable refrigerating for data devices in a data center.

The invention provides the following technical solutions in order to solve the above technical problem.

One aspect of the invention provides an air conditioner terminal device comprising an air passage communicating from an air suction port to an air discharge port, wherein a heat exchanger and a variable-speed fan which forces air in the air passage to flow towards the air discharge port from the air suction port are installed in the air passage, and both the air suction port and the air discharge port are open downwardly.

Optionally, in the above air conditioner terminal device, oil-free refrigerant flows in the heat exchanger, and the refrigerant makes heat contact with air flowing through the air passage in the heat exchanger.

Optionally, in the above air conditioner terminal device, the air passage comprises a heat-exchanging segment and a fan segment, the heat exchanger is located within the heat-exchanging segment and the fan is located within the fan segment.

Optionally, in the above air conditioner terminal device, the air conditioner terminal device comprises a first frame and a second frame which are assembled together, wherein the first frame has the heat-exchanging segment of the air passage therein, and the second frame has the fan segment of the air passage therein.

Another aspect of the invention provides an air conditioning apparatus comprising the above-described air conditioner terminal device, a condenser, a pump and a circulating pipeline communicating the air conditioner terminal device, the condenser and the pump, wherein the pump forces refrigerant to circulate between the air conditioner terminal device and the condenser via the circulating pipeline.

Yet another aspect of the invention provides a data center comprising a plurality of data device racks and the above-described air conditioning apparatus, wherein each rack has opposite first and second sides, one said air conditioner terminal device is provided above each rack, the air suction port is located above the first side and the air discharge port is located above the second side.

According to the invention, since the air conditioner terminal device is provided with the air suction port and the air discharge port, both of which are open downwardly so that air can flow vertically into the air conditioner terminal device via the air suction port which is open downwardly, and flow vertically out of the air conditioner terminal device via the air discharge port which is open downwardly, an approximately U-shaped air flow having a vertical inflow of air and a vertical outflow of air is formed. Though the air conditioner terminal device is small in volume, it can effectively remove heat load generated by electronic loads inside data device racks in the data center, thus helping to eliminate heat influence from other data device racks which can prevent the heat bypass and save energy. Therefore, total refrigerating capacity requirement of the air conditioner terminal device is reduced.

On the other hand, since the air conditioner terminal device comprises the first frame and the second frame which are assembled together to define the air passage, the maintenances of the heat exchanger and the fan can be made independently. When one of the heat exchanger and the fan is damaged, the replacement or maintenance of one of the heat exchanger and the fan will not affect the other one. For example, when the fan has any problem, the maintenance personnel can repair and replace the malfunctioning fan very easily without having to disconnect the connecting pipeline of the heat exchanger. Thus, not only the maintenance is made easily and quickly, but also the risk of damaging elements inside the first frame is reduced; likewise, when the heat exchanger needs to be replaced due to malfunction or needs to be cleaned regularly, the maintenance personnel can also replace the heat exchanger very easily without having to remove the second frame in which the fan connected to the wires and control board is located, thus reducing the risk of damaging elements inside the second frame. Therefore, the air conditioner terminal device having the two-piece frame design can be easily installed and repaired, thus reducing the working load for installation and maintenance and improving the reliability of the air conditioner terminal device.

Other aspects and features of the invention will become apparent from the detailed description made below with reference to the accompanying drawings. However, it should be understood that the accompanying drawings are designed only for explanation purpose, rather than limiting the scope of the invention which should be referred to the appended claims. It should be also noted that unless otherwise indicated, the drawings are not necessarily drawn to scale, since they merely attempt to schematically depict the structure and workflow described herein.

### BRIEF DESCRIPTION OF THE DRAWINGS

The invention will be more fully understood with reference to the following detailed description of the embodiments when read in conjunction with the accompanying drawings in which like reference numbers denote like elements, wherein:

FIG. 1 is a schematic structural view of an air conditioner terminal device in accordance with an embodiment;

FIG. 2 is a schematic perspective view of an air conditioner terminal device in accordance with an embodiment, with an outer frame being transparentized and shown in double dot dash lines in order to illustrate the structure in an air passage; and

FIG. 3 is a schematic structural view of a data center in accordance with an embodiment

### DETAILED DESCRIPTION OF THE INVENTION

The embodiments of the invention will be described in detail below with reference to the accompanying drawings in order that the above objectives, features and advantages of the invention will become more apparent and more easily understood.

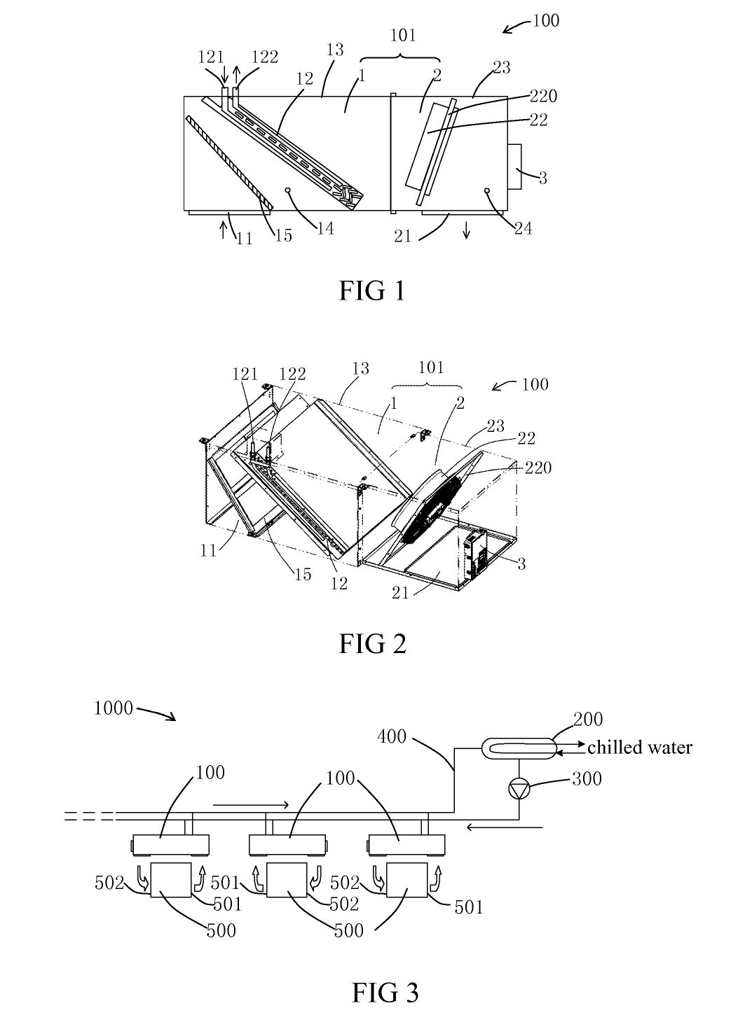

FIGS. 1 and 2 illustrate a structural view of an air conditioner terminal device in accordance with an embodiment, wherein FIG. 1 is an overall schematic structural view of the air conditioner terminal device, and FIG. 2 is a schematic perspective view of the air conditioner terminal device. As shown in FIGS. 1 and 2, the air conditioner terminal device 100 in accordance with an embodiment comprises an air passage 101 communicating from an air suction port 11 to an air discharge port 21. A heat exchanger 12 and a variable-speed fan 22 which forces air in the air passage 101 to flow towards the air discharge port 21 from the air suction port 11 are installed in the air passage 101. Both the air suction port 11 and the air discharge port 21 are open downwardly.

Since the air conditioner terminal device 100 is provided with the air suction port 11 and the air discharge port 21, both of which are open downwardly so that air can flow vertically into the air conditioner terminal device 100 via the air suction port 11 which is open downwardly, and flow vertically out of the air conditioner terminal device 100 via the air discharge port 21 which is open downwardly, an approximately U-shaped air flow having a vertical inflow of air and a vertical outflow of air is formed and an effective air circulation is realized, which can effectively remove heat load generated by electronic loads inside data device racks in the data center, and help to eliminate heat influence from other data device racks which can prevent the heat bypass and save energy. Therefore, total refrigerating capacity requirement of the air conditioner terminal device 100 is reduced and the reliability of the air conditioner terminal device 100 is improved.

The heat exchanger 12 employs oil-free refrigerant inside, for example, carbon dioxide is used as the refrigerant. The oil-free refrigerant flows in the heat exchanger 12 and makes heat contact with air flowing through the air passage 101, thereby effecting heat-exchanging. Since the oil-free refrigerant is used inside the heat exchanger 12, not only an excellent heat-exchanging performance can be obtained, but also a clean environment inside the data center can be reliably maintained.

The air passage 101 comprises a heat-exchanging segment 1 and a fan segment 22. The heat exchanger 12 is located within the heat-exchanging segment 1 and the fan 22 is located within the fan segment 22.

In an optional embodiment, the air conditioner terminal device 100 comprises a first frame 13 and a second frame 23 which are assembled together. The first frame 13 has the heat-exchanging segment 1 of the air passage 101 therein, and the second frame 23 has the fan segment 2 of the air passage 101 therein. The first frame 13 and the second frame 23 engage tightly with each other to form the continuous, closed air passage 101. Optionally, the first frame 13 and the second frame 23 can be separated so that they can be detached and assembled conveniently. In an embodiment, both the first frame 13 and the second frame 23 are aluminum alloy frames.

Since the air conditioner terminal device 100 employs a two-piece frame design, i.e., the first frame 13 and the second frame 23, the heat exchanger 12 and the fan 22 can be respectively assembled in different frames so that the two-piece frames can be easily connected and even can be assembled on site. For example, the heat exchanger 12 can be assembled in the first frame 13 and the fan 22 can be assembled in the second frame 23. The maintenances of the heat exchanger 12 and the fan 22 are independent. When one of the heat exchanger 12 and the fan 22 is damaged and needs to be replaced or repaired, the other of the heat exchanger 12 and the fan 22 will not be affected. For example, when the fan 22 has any problem, the maintenance personnel can repair and replace the malfunctioning fan 22 very easily without having to disconnect the connecting pipeline of the heat exchanger 12, thus reducing the risk of damaging elements inside the first frame 13; likewise, when the heat exchanger 12 needs to be replaced due to malfunction or needs to be cleaned regularly, the maintenance personnel can also replace the heat exchanger 12 very easily without having to remove the second frame 23 in which the fan 22 connected to the wires and control board is located, thus reducing the risk of damaging elements inside the second frame 23. Therefore, the air conditioner terminal device 100 having the two-piece frame design can be easily installed and repaired, thus reducing the working load for installation and maintenance and improving the reliability of the air conditioner terminal device 100.

The air conditioner terminal device 100 comprises a fan plate 220 extending across the whole of the air passage 101. The fan plate is provided with a fan hole (not shown in the figures) therein and the fan 22 is installed in the fan hole.

In an embodiment, the heat exchanger 12 is a coil heat exchanger 12 having an inlet 121 and an outlet 122. The refrigerant of the heat exchanger 12 flows in via the inlet 121 and flows out from the outlet 122 after circulating through the heat exchanger 12. The inlet 121 and the outlet 122 of the heat exchanger 12 are disposed at a top of the first frame 13.

Optionally, the heat exchanger 12 is a copper tube structure with aluminum fins, wherein phase transitioned refrigerant is inside the tube, and air flow is outside the tube. The refrigerant is liquid-phase when entering the inlet 121 of the heat exchanger 12 and is gas-liquid two-phase or gas-phase when reaching the outlet 122 of the heat exchanger 12 after conducting heat-exchanging with air via copper tubes when circulating inside tubes.

The air suction port 11 is a bottom opening in the first frame 13, and an end of the first frame 13 that is adjacent to the air suction port 11 is closed. A first temperature sensor 14 is provided between the air suction port 11 and the heat exchanger 12 for detecting inflow air temperature. In an optional embodiment, an air filter 15 is also provided between the air suction port 11 and the heat exchanger 12 and the first temperature sensor 14 is located between the air filter 15 and the heat exchanger 12, that is, the air filter 15 is located above the air suction port 11, the heat exchanger 12 is located downstream of the air filter 15, and the first temperature sensor 14 is provided between the air filter 15 and the heat exchanger 12. All of the heat exchanger 12, the air filter 15 and the first temperature sensor 14 are installed inside the first frame 13, wherein the air filter 15 can be detached flexibly from an installing opening at a lower portion of the first frame 13.

The air discharge port 21 is a bottom opening in the second frame 23. A second temperature sensor 24 is provided between the air discharge port 21 and the heat exchanger 12. In an embodiment, the second temperature sensor 24 is provided between the air discharge port 21 and the fan 22, that is, the second temperature sensor 24 is disposed downstream of the fan 22 and upstream of the air discharge port 21 for detecting outflow air temperature. The second temperature sensor 24 and the fan 22 are installed inside the second frame 23.

The air conditioner terminal device 100 further comprises a controller 3, and all of the control functions of the controller 3 can be realized by use of a single chip microcomputer. The controller 3 is fixed onto an outer sidewall surface of a closed end of the second frame 23. The controller 3 is associated with the first temperature sensor 14, the second temperature sensor 24 and the fan 22.

The air conditioner terminal device 100 uses the first temperature sensor 14, the second temperature sensor 24 and the controller 3 to control the rotational speed of the fan 22. In an embodiment, the fan 22 is a variable-frequency axial flow fan 22 which, by means of the controller 3, automatically adjusts its rotational speed according to temperature difference between the first temperature sensor 14 and the second temperature sensor 24. Two input ends of the controller 3 are connected with the first temperature sensor 14 and the second temperature sensor 24 respectively, and the output end thereof is connected with an inverter of the variable-frequency axial flow fan 22. For example, the controller 3 receives temperature signals from the first temperature sensor 14 and the second temperature sensor 24, automatically calculates a temperature difference between the inflow air temperature and the outflow air temperature, and compares the temperature difference with a temperature difference set value so as to output a frequency signal of the fan 22 according to a corresponding control logic, thus adjusting the rotational speed of the fan 22, varying air volume of the fan 22 and achieving the goal of automatic adjustment of refrigerating capacity.

When other air conditioner terminal devices of the data center can not provide effective refrigerating due to malfunction, air temperature at the air suction port 11 will rise. When the temperature difference between the inflow air temperature detected by the first temperature sensor 14 and the outflow air temperature detected by the second temperature sensor 24 exceeds the temperature difference set value, the controller 3 will raise the frequency of the fan 22 automatically so as to enlarge circulating air volume. Meanwhile, the operation control of cold source device will be made an adjustment accordingly. For example, the flow rate of chilled water which exchanges heat with the refrigerant will be increased, and even the water supplying temperature set of the chilled water can be lowered so as to meet higher heat dissipation requirements. The air conditioner terminal device 100 is an air conditioner terminal device 100 whose refrigerating capacity is automatically adjustable, i.e., the air conditioner terminal device 100 can automatically adjust the rotational speed of the fan according to a temperature difference signal from the first temperature sensor 14 and the second temperature sensor 24, and further automatically adjust the refrigerating capacity of the air conditioner terminal device 100 by adjusting the rotational speed of the fan.

The air conditioner terminal device 100 is simple and compact in structure, and has a high refrigerating capacity which is adjustable. The air conditioner terminal device 100 can deal with high heat load density, effectively cool down electronic loads having high heat density, and meet control requirements on machine room environment of the data center. Besides, the air conditioner terminal device 100 can automatically adjust refrigerating capacity according to change of machine room heat load so as to ensure normal operation of IT devices and improve reliability of air conditioning system. Meanwhile, refrigerating capacity can be increased automatically when malfunction happens to other air conditioner terminal devices of the data center, thereby reducing redundancy of components of the air conditioning system and lowering cost.

The air conditioner terminal device 100 has such advantages as good applicability, high utilizing rate of device, considerable energy saving effect, and excellent technical and economic performance, etc., and has a fine prospect of commercial development and application.

As shown in FIG. 3, an air conditioning apparatus comprises the above-described air conditioner terminal device 100, a condenser 200, a pump 300 and a circulating pipeline 400 communicating the air conditioner terminal device 100, the condenser 200 and the pump 300. The pump 300 forces refrigerant to circulate between the air conditioner terminal device 100 and the condenser 200 via the circulating pipeline 400.

In an optional embodiment, the air conditioning apparatus comprises more than two air conditioner terminal devices 100. In the data center shown in FIG. 3, the air conditioning apparatus illustratively comprises three air conditioner terminal devices 100. However, the number of air conditioner terminal devices 100 contained in the air conditioning apparatus is not limited to be three. The number of air conditioner terminal devices 100 contained in the air conditioning apparatus can be appropriately chosen according to the amount of heat load generated by electronic loads in the data center.

Unlike conventional air conditioning devices, the air conditioning apparatus in accordance with the embodiment of the invention utilizes appropriate configuration so that a liquid phase refrigerant performs phase transition heat release in the heat exchanger 12 so as to leave the heat exchanger in gas-liquid two-phase or gas-phase. The circulating pipeline 400 between the condenser 200 and the heat exchanger 12 of the air conditioner terminal device 100 is not provided with a throttle device. The throttle device comprises an expansion valve or a capillary, etc. For example, in an embodiment, carbon dioxide is used as the refrigerant, of which the pressure ranges from 39 bar to 72 bar and the operating temperature ranges from 5 to 30□, and the flow rate of refrigerant in each air conditioner terminal device 100 is 0.1 to 1 m3/hour. In an embodiment, the condenser 200 is a water-cooling condenser 200.

Further, as shown in FIG. 3, a schematic structural view of a data center 1000 of an embodiment is disclosed. The data center 1000 of the embodiment comprises a plurality of data device racks 500 and the above-described air conditioning apparatus. Each data device rack 500 comprises opposite first side 501 and second side 502. One said air conditioner terminal device 100 is provided above each rack 500, the air suction port 11 is located above the first side 501 of the data device rack 500 and the air discharge port 21 is located above the second side 502 of the data device rack 500.

Likewise, in the data center 1000 shown in FIG. 3, only three data device racks 500 and three air conditioner terminal devices 100 provided above the data device racks 500 have been schematically illustrated. However, the numbers of data device racks 500 and corresponding air conditioner terminal devices 100 provided above the data device racks 500 contained in the data center 1000 can be appropriately chosen according to actual application conditions of the data center 1000.

In the data center 1000, the air suction port 11 of the air conditioner terminal device 100 is located above the first side 501 of the data device rack 500, and the air discharge port 21 is located above the opposite second side 502 of the data device rack 500. In an embodiment, the first sides 501 of two adjacent rows of data device racks 500 face each other to form a first passage therebetween, and the second sides 502 of two adjacent rows of data device racks 500 face each other to form a second passage therebetween. Therefore, the air suction ports 11 of two adjacent air conditioner terminal devices 100 are close to each other and are located above the first passage between the data device racks 500, and the air discharge ports 21 of two adjacent air conditioner terminal devices 100 are close to each other and are located above the second passage between the data device racks 500. Apparently, the first passage has a higher temperature and is therefore the “hot passage” since inside the first passage, there is hot air to back to the air conditioner terminal device 100; and the second passage has a lower temperature and is therefore the “cold passage” since inside the second passage, there is cold air flowing out from the air conditioner terminal device 100. These “hot passage” and “cold passage” form an air curtain so as to prevent heat interference between the data device racks 500, thus realizing effective and reliable air circulation and improving refrigerating capacity of the air conditioner terminal device 100.

The air circulating process in the machine room of the data center 100 under a refrigerating working condition is described as follows. Hot air inside the “hot passage” between the data device racks 500 enters the air passage of the air conditioner terminal device 100 via the air suction port 11, and sequentially flows through the air filter 15, the heat exchanger 12 and the fan 22 of the air conditioner terminal device 100, and is then discharged into the “cold passage” via the air discharge port 21, and finally flows through the data device racks 500, returns to the “hot passage” after absorbing heat generated by electronic loads such as data devices, thus completing one cycle.

When other air conditioner terminal devices 100 of the data center 1000 can not provide effective refrigerating due to malfunction, air temperature in the “hot passage” will rise. When the temperature difference between the inflow air temperature detected by the first temperature sensor 14 and the outflow air temperature detected by the second temperature sensor 24 exceeds the temperature difference set value, the controller 3 will raise the frequency of the fan 22 automatically so as to enlarge circulating air volume and increase refrigerating capacity automatically, thus ensuring normal operation of data devices in the data center 1000. Meanwhile, redundancy design of the air conditioner terminal device 100 can be reduced and overall cost of the data center 1000 is lowered.

The above embodiments only serve for explaining the invention rather than limiting the invention. Those skilled in the art can make various modifications and variations without departing from the spirit and scope of the invention. Therefore, all the equivalent technical solutions also pertain to the scope of the invention and the protection scope of the invention should be defined by the appended claims.

What is claimed is:

1. An air conditioner terminal device comprising an air passage communicating from an air suction port to an air discharge port, wherein a heat exchanger and a variable-speed fan which forces air in the air passage to flow towards the air discharge port from the air suction port are installed in the air passage, wherein both the air suction port and the air discharge port are open downwardly
wherein the air passage comprises a heat-exchanging segment and a fan segment, the heat exchanger is located within the heat-exchanging segment and the fan is located within the fan segment; and
further comprising a first frame and a second frame which are assembled together, wherein the first frame has the heat-exchanging segment of the air passage therein, and the second frame has the fan segment of the air passage therein.

2. The air conditioner terminal device according to claim 1, wherein oil-free refrigerant flows in the heat exchanger, and the refrigerant makes heat contact with air flowing through the air passage in the heat exchanger.

3.-4. (canceled)

5. The air conditioner terminal device according to claim 1, wherein a first temperature sensor is provided between the air suction port and the heat exchanger.

6. The air conditioner terminal device according to claim 5, wherein a second temperature sensor is provided between the air discharge port and the heat exchanger.

7. The air conditioner terminal device according to claim 5, wherein an air filter is provided between the air suction port and the heat exchanger, and the first temperature sensor is located between the air filter and the heat exchanger.

8. The air conditioner terminal device according to claim 1, comprising a fan plate extending across the whole flow section of the air passage, wherein the fan plate is provided with a fan hole therein and the fan is installed in the fan hole.

9. The air conditioner terminal device according to claim 6, further comprising a controller which is associated with the first temperature sensor, the second temperature sensor and the fan.

10. The air conditioner terminal device according to claim 9, wherein the fan is a variable-frequency axial flow fan which, by means of the controller, automatically adjusts its rotational speed according to temperature difference between the first temperature sensor and the second temperature sensor.

11. The air conditioner terminal device according to claim 1, wherein the first frame and the second frame can be separated.

12. The air conditioner terminal device according to claim 1, wherein the heat exchanger is a coil heat exchanger having an inlet and an outlet, the refrigerant of the heat exchanger flows in via the inlet, and flows out from the outlet after circulating through the heat exchanger.

13. The air conditioner terminal device according to claim 12, wherein the heat exchanger is a copper tube structure with aluminum fins, the refrigerant is liquid-phase when entering the inlet, and is gas-liquid two-phase or gas-phase when reaching the outlet after circulating through the copper tube.

14. The air conditioner terminal device according to claim 12, wherein the inlet and the outlet are disposed at a top of the first frame.

15. An air conditioning apparatus, characterized by comprising the air conditioner terminal device according to claim 1, a condenser, a pump and a circulating pipeline communicating the air conditioner terminal device, the condenser and the pump, wherein the pump forces refrigerant to circulate between the air conditioner terminal device and the condenser via the circulating pipeline.

16. The air conditioning apparatus according to claim 15, wherein the circulating pipeline between the condenser and the heat exchanger of the air conditioner terminal device is not provided with a throttle device.

17. The air conditioning apparatus according to claim 15, wherein the condenser is a water-cooling condenser.

18. The air conditioning apparatus according to claim 15, comprising more than two air conditioner terminal devices.

19. A data center comprising a plurality of data device racks and the air conditioning apparatus according to claim 1, wherein each rack has opposite first and second sides, one said air conditioner terminal device is provided above each rack, the air suction port is located above the first side and the air discharge port is located above the second side.

20. The data center according to claim 19, wherein the first sides of the two adjacent data device racks face each other to form a first passage therebetween, and the second sides of the two adjacent data device racks face each other to form a second passage therebetween, the air suction ports of two adjacent air conditioner terminal devices are close to each other and are located above the first passage between the data device racks, and the air discharge ports of two adjacent air conditioner terminal devices are close to each other and are located above the second passage between the data device racks.
